(19) United States
(12) Patent Application Publication
(10) Pub. No.: US 2007/0278541 A1
(43) Pub. Date: Dec. 6, 2007

(54) Spacer engineering on CMOS devices

(75) Inventors: Chien-Chao Huang, Hsin-Chu (TW); Fu-Liang Yang, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/446,912

(22) Filed: Jun. 5, 2006

(51) Int. Cl. H01L 29/76

(52) U.S. Cl. 257/288

(57) ABSTRACT

A MOS device having a reduced LDD dopant diffusion length and a method for forming the same are provided. The MOS device includes a gate stack over a semiconductor substrate, a spacer liner on a sidewall of the gate stack and having a portion over the semiconductor substrate, and a spacer over the spacer liner. The spacer for a PMOS device preferably has a tensile stress, and the spacer for an NMOS device preferably has a compressive stress.

### TECHNICAL FIELD

This invention relates generally to semiconductor devices, and more particularly to the structures and fabrication methods of metal-oxide-semiconductor (MOS) devices.

### BACKGROUND

As the dimensions of transistors are scaled down, reducing vertical junction depth and suppressing dopant lateral diffusion in order to control short-channel characteristics become greater challenges. Particularly, with very short distances between source and drain regions, dopant diffusion may cause a significant increase in the leakage current. Controlling dopant diffusion length thus becomes very important.

To reduce the dopant diffusion length, diffusion time needs to be decreased. Many methods have been developed to reduce annealing time in order to reduce diffusion time. For example, spike annealing and flash annealing were used to replace the conventional thermal annealing. Laser annealing, which uses less time, has also been developed. Additionally, using low-temperature processes to reduce thermal budget also leads to the reduction of the dopant diffusion length.

Another commonly used method for reducing the effects of dopant diffusion is to form pocket regions, so that lightly doped drain/source (LDD) regions with sharp profiles can be formed. However, with MOS devices becoming smaller, heavy pocket doping is required. When the pocket regions on the source and drain sides get too close, even very small diffusion causes significant leakage current between the source and drain. The MOS devices thus cannot be turned off effectively.

Therefore, to meet the ever-increasing requirement of reducing dopant diffusion length, new methods are needed.

### SUMMARY OF THE INVENTION

In accordance with one aspect of the present invention, a MOS device includes a gate stack over a semiconductor substrate, a spacer liner on a sidewall of the gate stack and having a portion over the semiconductor substrate, and a spacer over the spacer liner. The spacer for a PMOS device preferably has a tensile stress, and the spacer for an NMOS device preferably has a compressive stress.

In accordance with another aspect of the present invention, a MOS device includes an NMOS device and a PMOS device formed on a substrate. The NMOS device includes a first gate stack over the semiconductor substrate, a first spacer liner on a sidewall of the first gate stack and having a portion over the semiconductor substrate, and a first spacer having a first stress on the spacer liner. The PMOS device includes a second gate stack over the semiconductor substrate, a second spacer liner on a sidewall of the second gate stack and having a portion over the semiconductor substrate, and a second spacer having a second stress on the spacer liner. In one preferred embodiment, the first stress is compressive and the second stress is tensile. In another preferred embodiment, the first stress is more compressive than the second stress with a difference of greater than about 500 MPa.

In accordance with yet another aspect of the present invention, a method for forming a MOS device includes forming a gate stack over a semiconductor substrate, forming a spacer liner on a sidewall of the gate stack and having a portion over the substrate, and forming a stressed spacer on the spacer liner. Preferably, the stressed spacer has a stress of greater than about 300 MPa.

In accordance with yet another aspect of the present invention, a method for forming a semiconductor structure includes forming an NMOS device and a PMOS device. The step of forming the NMOS device includes forming a first gate stack over the semiconductor substrate, forming a first spacer liner on a sidewall of the first gate stack and having a portion over the semiconductor substrate, and forming a first spacer having a first stress on the spacer liner. The step of forming the PMOS device includes forming a second gate stack over the semiconductor substrate, forming a second spacer liner on a sidewall of the second gate stack and having a portion over the semiconductor substrate, and forming a second spacer having a second stress on the spacer liner, wherein the second stress is substantially more tensile than the first stress.

With stress applied to LDD regions by the stressed spacers, the dopant diffusion length is reduced.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 3 illustrate the relationship between stressed films and dopant diffusion lengths;

FIG. 4 illustrates regions in the substrate affected by stress in the spacers;

FIGS. 5 through 10 are cross-sectional views of intermediate stages in the manufacture of a preferred embodiment;

FIG. 11 illustrates a comparison between threshold voltages of NMOS devices having stressed spacers and threshold voltages of NMOS devices having non-stressed spacers; and

FIG. 12 illustrates a comparison between threshold voltages of PMOS devices having stressed spacers and threshold voltages of PMOS devices having non-stressed spacers.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Fick's second law has stated that the diffusion length of dopants is proportional to (Dt)^{1/2}, wherein D is the diffusion index, and t is the diffusion time. The diffusion index D can be further expressed as:

D=D₀ e^{(-Δ}G/KT) [Eq. 1]

wherein D₀ is the intrinsic diffusion index, G represents Gibbs free energy, and T is the absolute temperature. This is in line with a known fact that low thermal budget processes, which involve reduced diffusion (annealing) time and lower diffusion (annealing) temperature, can lower the diffusion length.

Fick's second law also indicates that diffusion length is related to Gibb free energy G. The reduction of diffusion length can also be achieved by increasing Gibb free energy G of dopants. Further research has revealed that the Gibb free energy G is related to the stress of the host material of the dopants. Therefore, a conclusion is made that the dopant diffusion length is related to stress.

There are two dopant diffusion mechanisms, vacancy mechanism and interstitial mechanism. Different dopants may diffuse with respect to different diffusion mechanisms, and the effects on the stresses to the diffusion of different dopants are also different.

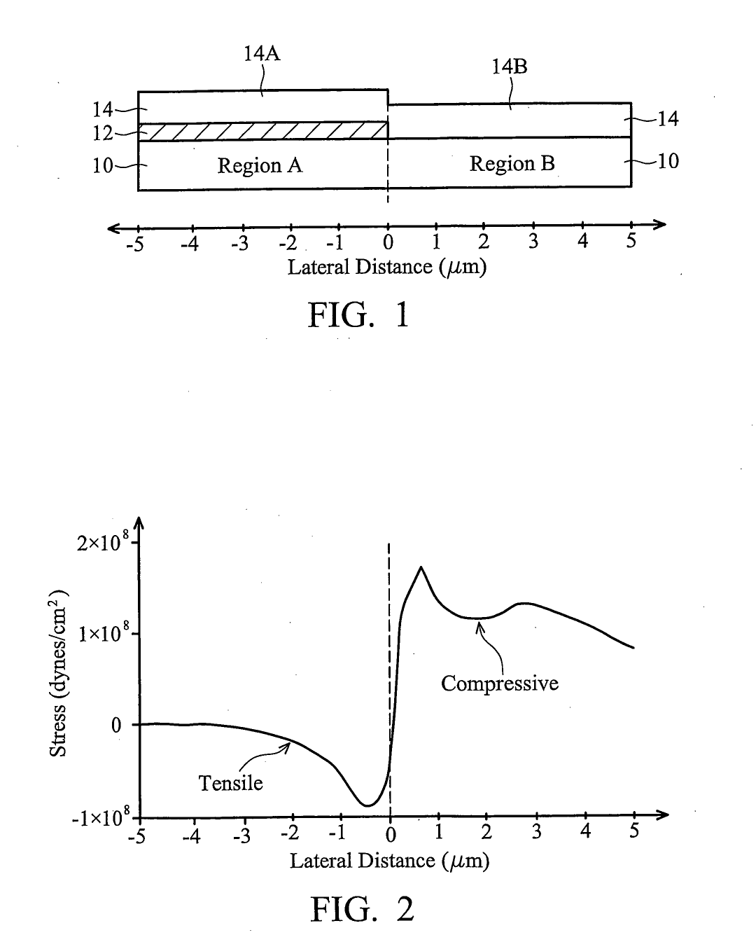

FIGS. 1 through 3 reveal how stresses affect the diffusion behavior of antimony (Sb). FIG. 1 illustrates a cross-sectional view of a sample. A silicon substrate 10 includes a region A and a region B. An oxide layer 12 having a thickness of about 400 Å is formed on substrate 10 in region A. A nitride layer 14 having an intrinsic tensile stress is formed over substrate 10. The portions of the nitride layer 14 over silicon regions A and B are denoted as 14A and 14B, respectively.

The stresses in silicon substrate 10 are shown in FIG. 2, wherein the X-axis corresponds to the X-axis in FIG. 1, which shows the lateral distance from the interface (dotted line) of the regions A and B. With a tensile-stressed film 14B directly on top of region B, silicon region B has a compressive stress. Conversely, with a 400 Å oxide layer between the silicon region A and the tensile-stressed film 14A, silicon region A has a tensile stress. As a general rule, if the thickness of the oxide layer 12 is reduced, the tensile stress in region A will become less tensile. By continually reducing the thickness of the oxide layer 12, the stress in region A eventually becomes compressive. Note that the same phenomenon can be observed if the thickness of the oxide layer 12 is fixed, while the tensile stress in film 14A is increased. With the increase of the tensile stress in film 14A, the stress in silicon region A become less tensile, and eventually becomes compressive. Therefore, to effectively generate a stress in region A, the silicon oxide layer 12 is preferably thin, and/or the stress in nitride layer 14A is preferably high, so that the resulting stress in region A is the opposite of the stress in the overlying film 14A.

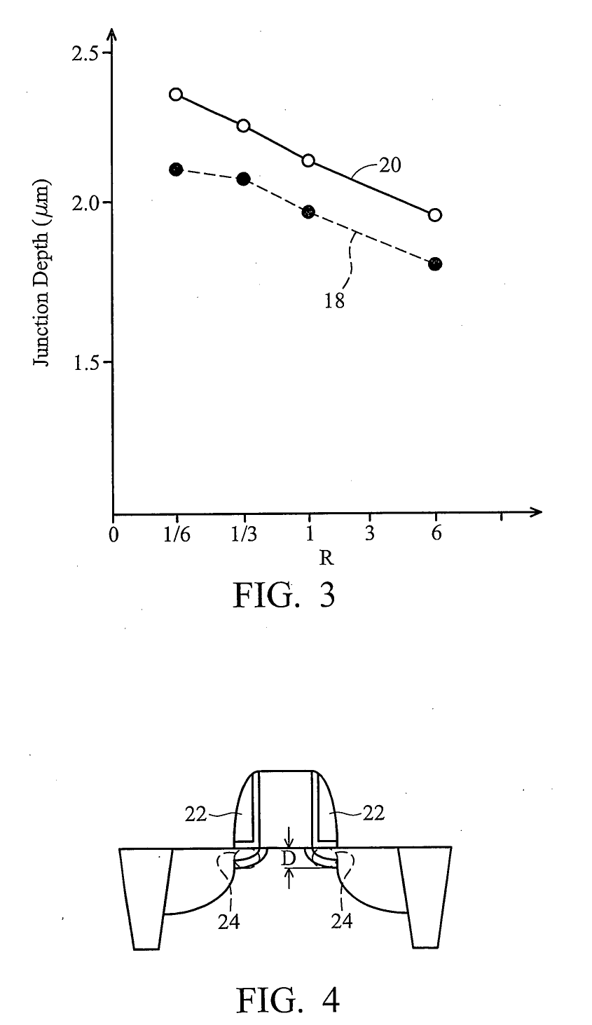

FIG. 3 illustrates the relationship between stress and diffusion length. The X-axis is the curvature R of the films 14A and 14B when they are under stress. A small curvature indicates a great compressive stress, while a great curvature indicates a small compressive stress. The Y-axis indicates junction depth, which reflects the diffusion length of Sb in regions A and B. Lines 18 and 20 reflect diffusion lengths in regions A and B, respectively. Comparing lines 18 and 20, it is noted that a compressive stress (line 20) causes a greater diffusion length of Sb, while a tensile stress causes a smaller diffusion length. Also, line 20 indicates that with the increase of compressive stress (with the decrease of R), diffusion length in silicon region B increases. From line 18, it is found that when the stress in nitride layer 14A becomes more compressive (thus R becomes smaller, although the stress in nitride layer 14A may be tensile), the diffusion length of Sb increases.

It can be concluded from FIGS. 1 through 3 that a compressive stress helps the diffusion of Sb, while a tensile stress works the opposite way. Accordingly, to decrease the diffusion length, a tensile stress is preferred in silicon region A, which means that the nitride layer 14A needs to have a compressive stress. The diffusion of Sb under compressive stress typically uses a vacancy mechanism.

Boron (B) and phosphorous (P), however, show a different behavior. Boron and phosphorous have greater diffusion lengths when under tensile stress, and smaller diffusion lengths when under compressive stress. Boron and phosphorous may diffuse using an interstitial mechanism.

In the preferred embodiment, the previously discussed results are used in the formation of gate spacers. To fully understand the effects of stress in gate spacers, a simulation has been performed by the inventors, and the result is schematically shown in FIG. 4. It has been found that the stresses in spacers 22 cause local stresses substantially limited to regions 24, which are small regions under the respective spacers 22. In an exemplary simulation result, the depth D of the regions 24 is about 200 Å. This depth is similar to the depth of the pocket regions of MOS devices that are formed using 65 nm technology. Note that LDD regions are typically shallower than the pocket regions, thus are substantially inside regions 24. The local stresses have small effects for regions not underlying the respective spacers 22.

Based on the above analysis, a preferred embodiment of the present invention is provided. The intermediate stages of manufacturing a preferred embodiment of the present invention are illustrated. Throughout the various views and illustrative embodiments of the present invention, like reference numbers are used to designate like elements.

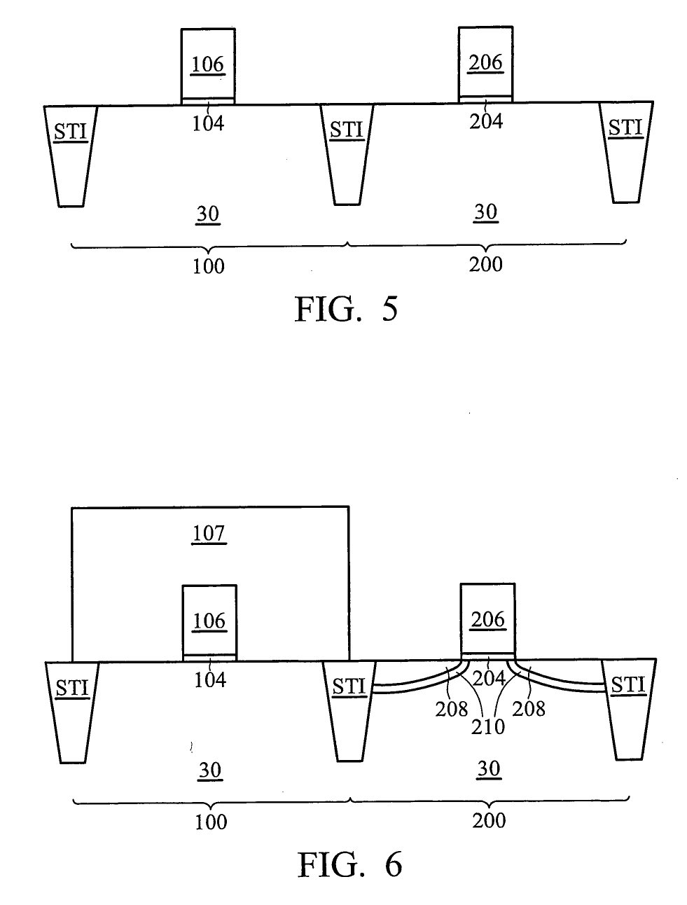

FIG. 5 illustrates a substrate 30 including two regions, a region 100 for forming a PMOS device and a region 200 for forming an NMOS device. Shallow trench isolations (STIs) isolate the device regions. A gate stack including a gate dielectric 104 and a gate electrode 106 is formed in the PMOS region 100. Similarly, a gate stack including a gate dielectric 204 and a gate electrode 206 is formed in the NMOS region 200. The gate dielectrics 104 and 204 preferably have high k values. Substrate 30 is preferably bulk silicon, but other commonly used materials and structures such as SiGe and silicon-on-insulator (SOI) can also be used.

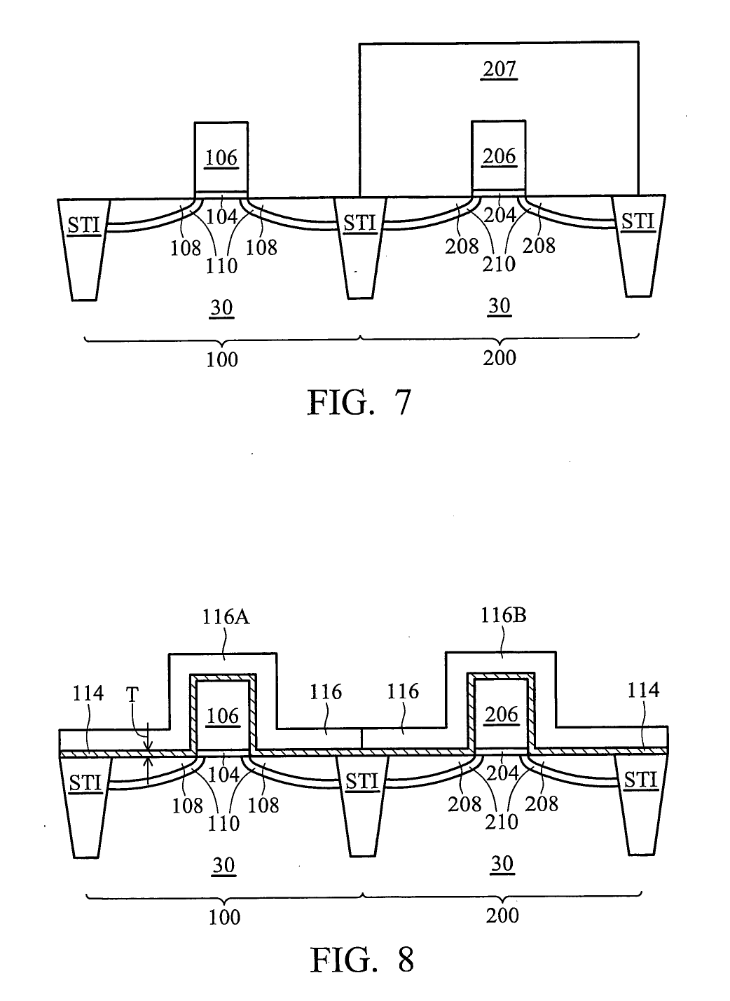

FIGS. 6 and 7 illustrate the formation of lightly doped drain/sources (LDD) for PMOS and NMOS devices. Referring to FIG. 6, a photo resist 107 is formed, masking PMOS region 100. N-type dopants, such as phosphorous, antimony, and arsenic (As), but more preferably antimony, are implanted into NMOS region 200. LDD regions 208 are formed substantially adjacent to the edges of the gate electrode 206, and preferably have a thickness of less than about 200 Å. Pocket regions 210 are preferably formed by tilt implanting, so as to extend further under the gate electrode 206 than the LDD regions 208 do. In the preferred embodiment, pocket regions 210 comprise P-type impurities, such as boron, indium, and the like. Photo resist 107 is then removed.

Similarly, FIG. 7 illustrates the formation of LDD regions 108 and pocket regions 110. A photo resist 207 is formed, covering NMOS region 200, and PMOS LDD regions 108 are then formed by doping a P-type impurity, preferably boron, into PMOS region 100. Pocket regions 110 are preferably formed by tilt implanting, so that the pocket regions 110 extend further under the gate electrode 206 then the LDD regions 108 do. In the preferred embodiment, pocket regions 110 comprise N-type impurities, such as phosphorus, arsenic, antimony, and the like. More preferably, phosphorus is used for pocket regions 110, while boron is used for forming LDD regions 108. Photo resist 207 is then removed.

In FIG. 8, a liner layer 114 is blanket formed. The liner layer 114 is preferably thin with a thickness T of less than about 40 Å, and more preferably less than about 20 Å. In the preferred embodiment, the liner layer 114 is a liner oxide formed using methods such as low pressure chemical vapor deposition (LPCVD), rapid thermal chemical vapor deposition (RTCVD), atomic layer chemical vapor deposition (ALCVD), and the like.

A spacer layer 116 is formed on the liner layer 114. Preferably the spacer layer 116 includes a portion 116A in region 100 and a portion 116B in region 200. In the preferred embodiment, spacer layer portion 116A has a tensile stress, which is preferably greater than about 300 MPa, and more preferably greater than about 500 MPa. Conversely, spacer layer portion 116B has a compressive stress, which is preferably greater than about 300 MPa, and more preferably greater than about 500 MPa. In other embodiments, both spacer layer portions 116A and 116B have compressive stresses with the stress in spacer layer portion 116A being less than the stress in spacer layer portion 116B, with the stress difference being preferably greater than about 500 MPa. In yet other embodiments, both spacer layer portions 116A and 116B have tensile stresses with the stress in spacer layer portion 116A being greater than the stress in spacer layer portion 116B, with the stress difference being preferably greater than about 500 MPa.

The liner layer 114 and spacer layer 116 may be formed using commonly used techniques, such as plasma enhanced chemical vapor deposition (PECVD), low-pressure chemical vapor deposition (LPCVD), sub-atmospheric chemical vapor deposition (SACVD), etc. In the preferred embodiment, spacer layer portions 116A and 116B both comprise silicon nitride, but have different stresses. As is known in the art, this can be achieved by forming spacer layer portions 116A and 116B separately using different formation methods and/or different process conditions. In an exemplary embodiment, atomic layer chemical vapor deposition (ALCVD) is used for forming spacer layer portion 116A while low pressure CVD is used for forming spacer layer portion 116B. Alternatively, a silicon nitride layer 116 is blanket formed, and a treatment such as UV curing or dopant implantation is performed to modify the stress in one of the spacer layer portions 116A and 116B, so that the desired stress difference is generated. In alternative embodiments, spacer layer portions 116A and 116B contain different materials, such as nitride, oxynitride, carbide, low k (k<3.0) oxide based materials, and the like, and are separately formed.

Spacer layer portions 116A and 1161B preferably have different compositions so that the resulting stresses are different. Typically, a nitrogen-rich nitride tends to be more tensile than a silicon-rich and/or oxygen-rich nitride. Therefore, to form silicon nitride layer 116B having high compressive stress or low tensile stress, the spacer layer portion 116B preferably comprises nitrides with a high concentration of silicon, for example, Si_{X}N with X being greater than about 0.75. As is known in the art, a silicon-rich nitride layer can be formed by adjusting process conditions, for example, increasing the flow rate of silane and/or reducing the flow rate of ammonia in a CVD process. In addition, oxygen may be used as one of the reaction gases to form silicon oxynitride. In the resulting structure, spacer layer portion 116B comprises oxygen while spacer layer portion 116A comprises no oxygen, and, at least, spacer layer portion 116B comprises more oxygen than spacer layer portion 116A.

Conversely, to form spacer layer portion 116A having high tensile or low compressive stress, the spacer layer portion 116A preferably comprises nitrides having a high concentration of nitrogen, for example, Si_{X}N with X being less than about 0.75. A nitrogen-rich nitride layer can be formed by adjusting process conditions, for example, reducing the flow rate of silane and/or increasing the flow rate of ammonia in a CVD process.

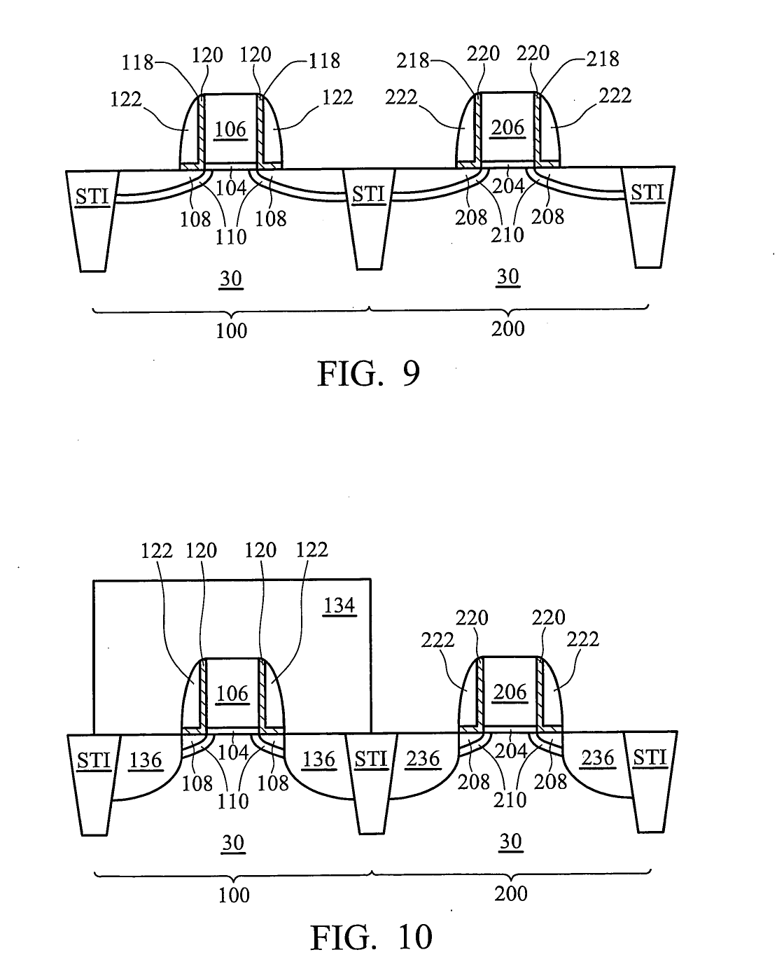

FIG. 9 illustrates the formation of gate spacers 118 and 218 by patterning liner layer 114 and spacer layer 116 in PMOS region 100 and NMOS region 200, respectively. Either wet etching or dry etching may be used for patterning. The resulting spacers 118 include liner portions 120 and spacer portions 122. Spacers 218 include liner portions 220 and spacer portions 222.

FIG. 10 illustrates the formation of deep source/drain regions 136 and 236 in PMOS region 100 and NMOS region 200, respectively. During the implantation, PMOS region 100 is masked by a photo resist 134, and deep source/drain regions 236 are formed by implanting N-type impurities. The photo resist 134 is then removed. Similarly, a photo resist (not shown) may be formed to mask NMOS region 200, and deep source/drain regions 136 are formed by implanting P-type impurities. In alternative embodiments, SiGe stressors (not shown) may be formed in source/drain regions 136 of the PMOS device.

An annealing is preferably performed to activate the implanted regions. In the preferred embodiment, annealing methods with short durations, such as laser annealing, spike annealing and flash annealing, are used. In other embodiments, thermal annealing with a longer duration may also be used due to better control of dopant diffusion length.

To finish the formation of the MOS devices, silicide regions (not shown) are formed on exposed surfaces of the source/drain regions and the gate electrodes of the MOS devices, followed by the formation of an etch stop layer (ESL) (not shown) and an inter-layer dielectric (ILD) (not shown). The details for forming the silicide regions, the ESL and the ILD are well known in the art, thus are not repeated herein.

In the resulting structure, spacers 122 have a high tensile stress or at least a low compressive stress, causing a more compressive stress in the LDD and/or pocket regions. The diffusion of dopants in LDD regions 108, and possibly pocket regions 210, is thus suppressed. Spacers 222 have a high compressive stress or at least a low tensile stress, causing a more tensile stress in the LDD and/or pocket regions. The diffusion of dopants in LDD regions 208 is thus suppressed. Liners 120 and 220 are thin, and thus local stresses are effectively generated in the respective LDD regions and pocket regions. The suppression of LDD dopants and pocket regions reduces the leakage currents between the source and drain regions.

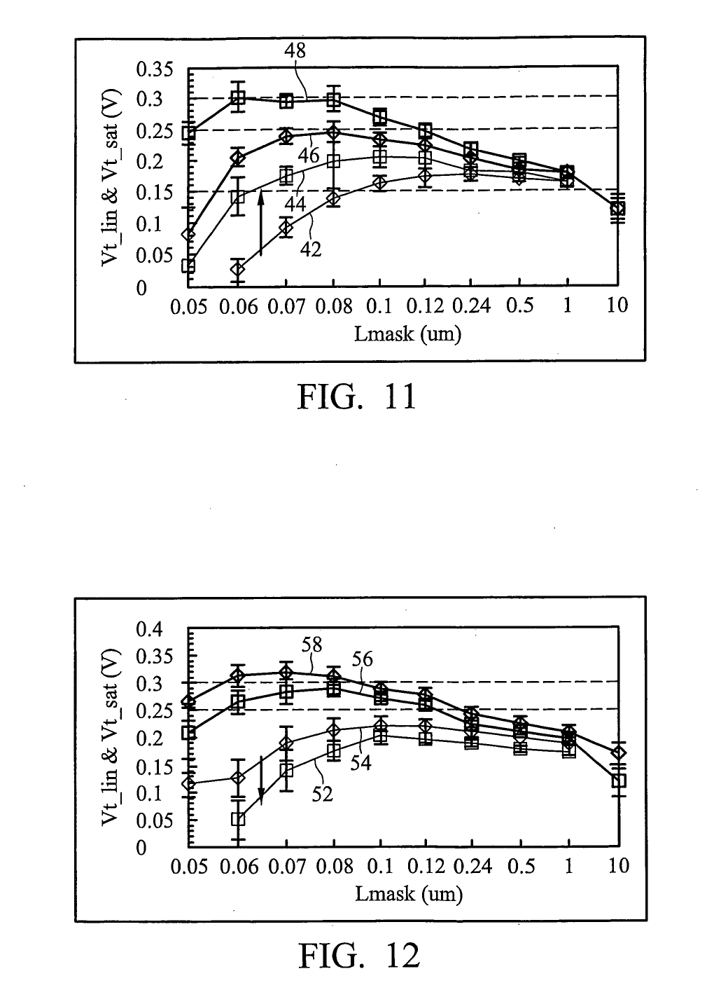

FIGS. 11 and 12 illustrate experiment results of NMOS devices and PMOS devices, respectively. Linear threshold voltages (for long channel devices) and saturation threshold voltages (for short channel devices) are shown as a function of the channel length Lmask. Referring to FIG. 11, lines 42 and 46 are obtained from NMOS devices with compressive stressed spacers, and lines 44 and 48 are obtained from NMOS devices with no stress in the spacers. Lines 42 and 44 show linear threshold voltages, while lines 46 and 48 show saturation threshold voltages. Comparing line 42 to line 44 (as well as line 46 to line 48), it is noted that by forming compressive-stressed spacers, both the linear threshold voltage and the saturation threshold voltage are increased.

Referring to FIG. 12, lines 52 and 56 are obtained from PMOS devices with tensile stressed spacers, and lines 54 and 58 are obtained from PMOS devices with no stress in the spacers. Lines 52 and 54 show linear threshold voltages, while lines 56 and 58 show saturation threshold voltages. Comparing line 52 to line 54 (as well as line 56 to line 58), it is noted that by using tensile-stressed spacers, the threshold voltages of NMOS devices are decreased, while the threshold voltages of PMOS devices are increased.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A MOS device comprising:
a semiconductor substrate;
a gate stack over the semiconductor substrate;
a spacer liner on a sidewall of the gate stack and having a portion over the semiconductor substrate; and
a spacer having a stress greater than about 300 MPa over the spacer liner.

2. The MOS device of claim 1, wherein the spacer liner has a thickness of less than about 40 Å.

3. The MOS device of claim 1 being an NMOS device, wherein the stress in the spacer is compressive.

4. The MOS device of claim 3 further comprising a lightly doped drain/source (LDD) region doped with antimony (Sb).

5. The MOS device of claim 3, wherein the spacer comprises silicon nitride, and wherein a ratio of an atomic number of silicon to an atomic number of nitrogen is greater than about 0.75.

6. The MOS device of claim 5, wherein the spacer further comprises oxygen.

7. The MOS device of claim 1 being a PMOS device, wherein the stress in the spacer is tensile.

8. The MOS device of claim 7 further comprising a LDD region comprising boron and a pocket region comprising phosphorous.

9. The MOS device of claim 7, wherein the spacer comprises silicon nitride, and wherein a ratio of an atomic number of silicon to an atomic number of nitrogen is less than about 0.75.

10. A semiconductor structure comprising:
a semiconductor substrate;
an NMOS device comprising
a first gate stack over the semiconductor substrate;
a first spacer liner on a sidewall of the first gate stack and having a portion over the semiconductor substrate; and
a first spacer on the first spacer liner; and
a PMOS device comprising
a second gate stack over the semiconductor substrate;
a second spacer liner on a sidewall of the second gate stack and having a portion over the semiconductor substrate; and
a second spacer on the second spacer liner, wherein the first and the second spacers have substantially different compositions.

11. The semiconductor structure of claim 10, wherein the first and the second spacer liners have a thickness of less than about 40 Å.

12. The semiconductor structure of claim 10, wherein the first spacer comprises a first silicon nitride and the second spacer comprises a second silicon nitride, and wherein a ratio of an atomic number of silicon to an atomic number of nitrogen of the first nitride is greater than about 0.75, and wherein a ratio of an atomic number of silicon to an atomic number of nitrogen of the second nitride is less than about 0.75.

13. The semiconductor structure of claim 10, wherein the first spacer comprises silicon oxynitride and the second spacer comprises silicon nitride.

14. The semiconductor structure of claim 10, wherein magnitudes of the first and the second stresses are greater than about 300 MPa.

15. The semiconductor structure of claim 10, wherein the first and the second stresses have a difference of greater than about 500 MPa.

16. A semiconductor structure comprising:
a semiconductor substrate;
an NMOS device comprising
a first gate stack over the semiconductor substrate;
a first spacer liner on a sidewall of the first gate stack and having a portion over the semiconductor substrate; and
a first spacer comprising a first silicon nitride on the first spacer liner, wherein an atomic number of silicon and an atomic number of nitrogen in the first silicon nitride have a first ratio; and
a PMOS device comprising
a second gate stack over the semiconductor substrate;
a second spacer liner on a sidewall of the second gate stack and having a portion over the semiconductor substrate; and
a second spacer comprising a second nitride on the second spacer liner, wherein an atomic number of silicon and an atomic number of nitrogen in the second silicon nitride have a second ratio, and wherein the second ratio is substantially greater than the first ratio.

17. The semiconductor structure of claim 16, wherein the second spacer is more tensile than the first spacer, and wherein a first stress in the first spacer and a second stress in the second spacer have a difference of greater than about 500 MPa.

18. The semiconductor structure of claim 16, wherein the first and the second spacer liners each have a thickness of less than about 40 Å.

19. The semiconductor structure of claim 16, wherein the first ratio is greater than about 0.75, and the second ratio is less than about 0.75.

20. The semiconductor structure of claim 19, wherein the first spacer comprises more oxygen than the second spacer.
